(19) United States
(12) Patent Application Publication
(10) Pub. No.: US 2025/0291240 A1
(43) Pub. Date: Sep. 18, 2025

(54) MRI Projector Viewing System

(71) Applicant: UX Platforms, Inc., La Jolla, CA (US)

(72) Inventors: Matthew Ferris, Encinitas, CA (US); Simon Whalen, San Diego, CA (US)

(21) Appl. No.: 18/603,704

(22) Filed: Mar. 13, 2024

Related U.S. Application Data
(63) Continuation-in-part of application No. 18/602,550, filed on Mar. 12, 2024.

(51) Int. Cl. G03B 21/56; G01R 33/28; G03B 21/28

(52) U.S. Cl. CPC G03B 21/56; G01R 33/283; G03B 21/28

(57) ABSTRACT

A projector projects images through an MRI bore of an MRI (Magnetic Resonance Imaging) system onto the back of a translucent screen. In some embodiments, the screen scatters light. When the light is focused on the back of the screen, an image is formed on the front of the screen. The image on the front of the screen is reflected by a mirror towards a patient receiving an MRI. In some embodiments, the mirror is retractable. In some embodiments, the mirror is mounted on a retractable arm. In some embodiments, the screen is mounted on side panels, which also support pivots. In some embodiments, the retractable arm pivots on the pivots that are supported on the side panels.

### CROSS REFERENCE TO RELATED APPLICATIONS

This application is a continuation-in-part of U.S. patent application Ser. No. 18/602,550, filed Mar. 12, 2024, Docket No. UX-001-PAP, entitled, “MRI BORE PROJECTOR SYSTEM” by MATTHEW FERRIS AND SIMON WHALEN, which is incorporated by reference.

### BACKGROUND

### (1) Technical Field

The disclosed method and apparatus relate generally to systems for projecting images. In particular, the disclosed method and apparatus relate to a system for projecting images to a patient, while undergoing an MRI (Magnetic Resonance Imaging) scan.

### (2) Background

Although projection systems are known, providing high-quality images to patients receiving an MRI (Magnetic Resonance Imaging) is problematic, because of the limitations of space within a MRI bore. Also, avoiding interference with the MRI imposes further limitations on the projector/screen system.

Accordingly, it would be advantageous to provide a system that can project high-quality images to a patient receiving an MRI without interfering with the MRI.

### SUMMARY

Various embodiments of a method and apparatus for a system and method for projecting images through an MRI bore of an MRI (Magnetic Resonance Imaging) system to a patient are disclosed.

A projector projects images through an MRI bore of an MRI system onto the back (or a first side) of a translucent screen, which in some embodiments scatters light, to form an image on the front (a second side) of the screen. The image on the front of the screen is reflected by a mirror to a patient receiving an MRI.

In some embodiments, the screen is attached to two side panels that hold the screen upright and attached to the bed of the MRI system. In some embodiments, the two side panels are partial arches and the screen and partial arches are shaped to fit the contour of the MRI bore. In some embodiments, the two side panels support a retracting arm, which in turn supports the mirror. The retracting arm allows the mirror to retract from a deployed position (which reflects light from the screen to the patient) to a retracted position allowing the patient to comfortably sit up and get out of, or onto, the bed of the MRI system. In some embodiments, the retracting arm is mounted, by pivots, to the side panels. The retracting arm rotates on the pivots. In some embodiments, a slot is mounted on each side panel. The retractable arm rests in the slots when the mirror is deployed. In some embodiments, the retracting arm is an arch. In some embodiments, connectors connect the mirror to the retracting arm. In some embodiments, the side panels are affixed to feet that engage the tracks, rails, or other structures of the bed.

### BRIEF DESCRIPTION OF THE DRAWINGS

The disclosed method and apparatus, in accordance with one or more various embodiments, is described with reference to the following figures. The drawings are provided for purposes of illustration only and merely depict examples of some embodiments of the disclosed method and apparatus. These drawings are provided to facilitate the reader's understanding of the disclosed method and apparatus. They should not be considered to limit the breadth, scope, or applicability of the claimed invention. It should be noted that for clarity and ease of illustration these drawings are not necessarily made to scale.

FIG. 1 illustrates some embodiments of an MRI (Magnetic Resonance Imaging) system in which an MRI projector viewing system has been installed.

FIG. 2 illustrates various embodiments of the screen assembly.

FIG. 3 illustrates a patient using the MRI projector viewing system of FIG. 1.

FIG. 4 illustrates the screen assembly without the MRI housing and a head coil.

FIG. 5 illustrates some embodiments of side panels that support a screen and a retractable arm.

FIG. 6 illustrates various embodiments of a screen onto which an image is projected.

FIG. 7 illustrates some embodiments of pivots that the retracting arm rotates upon.

FIG. 8 illustrates some embodiments of the retracting arm that supports a mirror.

FIG. 9 illustrates some embodiment of the mirror, which reflects images to the patients.

FIG. 10 illustrates an embodiment of a connector that connects the mirror to the retracting arm.

FIG. 11 illustrates a cross-section of a trough in the bed attached to the bed.

FIG. 12 illustrates an embodiment of a foot that attaches the side panels to a plate on the bed.

FIG. 13 illustrates some embodiments of an MRI system, using different feet than the system of FIG. 2.

FIG. 14 illustrates some embodiments of the feet of the MRI system of FIG. 13.

FIG. 15 illustrates some embodiments of a method projecting images, via the projector viewing system of FIGS. 1-12 to a patient while undergoing an MRI.

FIG. 16 illustrates some embodiments of a method of setting up the projector system of FIG. 1.

The figures are not intended to be exhaustive or to limit the claimed invention to the precise form disclosed. It should be understood that the disclosed method and apparatus can be practiced with modification and alteration, and that the invention should be limited only by the claims and the equivalents thereof.

### DETAILED DESCRIPTION

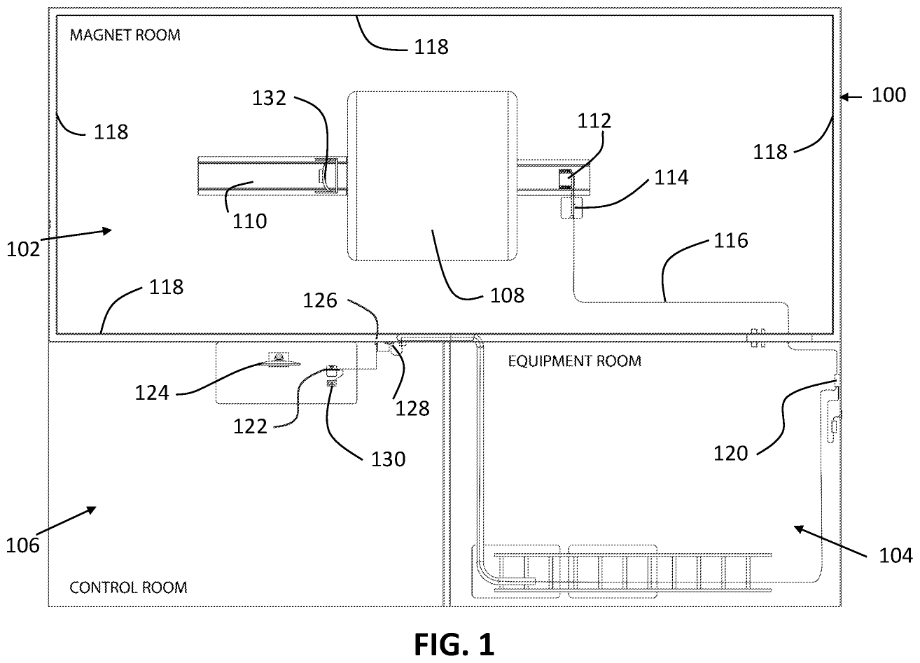

FIG. 1 illustrates some embodiments of an MRI (Magnetic Resonance Imaging) system 100 in which an MRI projector system has been installed. The MRI system includes a magnet room 102, an equipment room 104 and a control room 106.

The MRI is taken in the magnet room 102, which is controlled from the control room 106. The magnet room 102 houses a magnet housing 108, a bed 110, a projector 112, a stand 114, a first part of a cable 116 and walls 118. The equipment room 104 houses a second part of the cable 116 and a server 120. The magnet housing 108 houses components of the MRI system related to the magnets and the bed 110. The patient lays on the bed 110 while the MRI is captured and while moving the patient in and out of a borehole in the magnet housing 108. In other embodiments, the bed 110 (and any bed referenced in this specification) is replaced with a couch. The projector 112 projects images (which are optical or visible images) onto walls of the borehole of the magnet housing 108. The stand 114 supports the projector 112 while the projector 112 is projecting images. The cable 116 carries communication signals from the server 120 to the projector 112 controlling the projector 112, enabling the server 120 to control the projector 112. Running programs that control the projector 112, on the server 120 instead of in the projector 112, allows the projector 112 to (1) have less processing power, (2) be lighter and (3) generate less electromagnetic radiation and heat. By generating less electromagnetic radiation, the projector 112 is less likely to interfere with the MRI. Since less heat is produced, the projector 112 is less likely to overheat. Also, since the projector 112 can be lighter, the projector/stand assembly can be more stable and less likely to sway or topple. In some embodiments, the cable 116 also carries the power to the projector 112. In some embodiments, the cable 116 is coaxial and quad-shielded so that electromagnetic radiation generated by the cable 116 does not interfere with the MRI. In some embodiments, the server 120 and the client device 122 communicate wirelessly. In some embodiments, an ethernet cable or other communications cable connects the client device 122 to the server 120.

In some embodiments, the walls 118 of the magnet room 102 shield the magnet room 102 from electromagnetic radiation from outside of the magnet room 102 that would otherwise interfere with the MRI. In some embodiments, the equipment room 104 houses equipment related to the MRI system 100.

The control room 106 houses devices via which users can control the MRI system 100. In some embodiments, some of the devices in the control room 106 such as a client device 122 and a computer 124, have interfaces, via which the users control the MRI and the projector 112. In some embodiments, the client device 122 is a tablet computer. A power supply 126 supplies/regulates power for an AP (Access Point) 128 and the client device 122. The AP 128 acts as a gateway to the server 120. An auxiliary audio switch 130 switches between playing the audio files stored in the server 120 and audio files stored elsewhere or in another network.

A screen assembly 132 receives the image projected by the projector 112 and transmits the image to the patient.

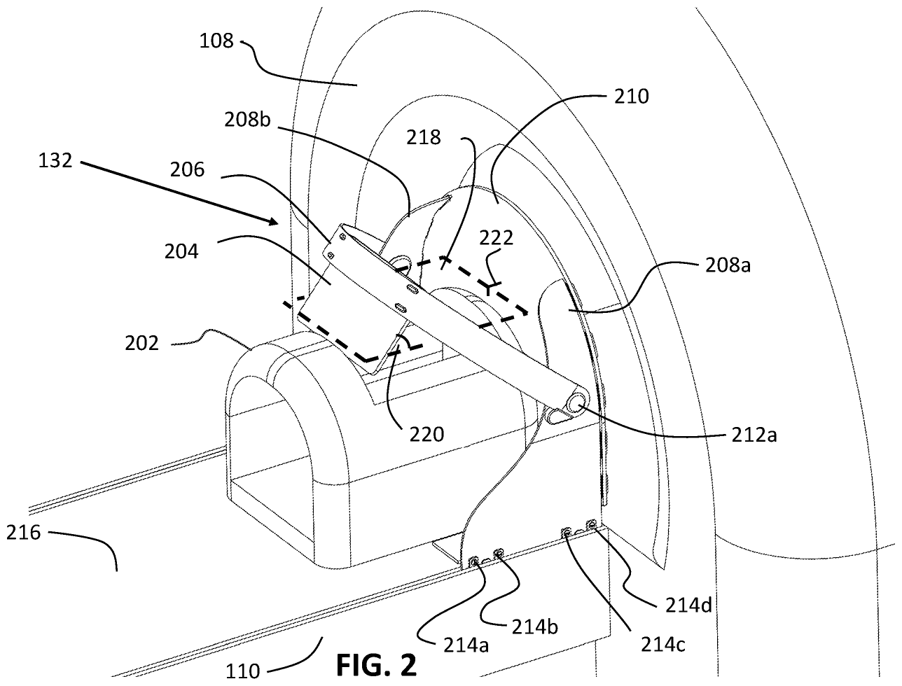

FIG. 2 illustrates various embodiments of the screen assembly 132. The screen assembly 132 includes a head coil 202, a mirror 204, a retractable arm 206, side panels 208a and b, a screen 210, pivots 212a and b, feet 214a-h, a bed surface 216, a viewing plane 218, an angle 220 and an angle 222.

The patient lies down with their head within the head coil 202, with their body extending away from the screen assembly 132. The head coil 202 produces or modifies the magnetic field for imaging a head of a patient. In other embodiments, the head coil 202 is replaced with or supplemented with a place for the patient to place their head. The screen assembly 132 rides on the bed 110 in and out of the MRI bore of the magnet housing 108. The mirror 204 is attached to the retractable arm 206, which retracts by pivoting or rotating on the pivots 212a and b. In some embodiments, the retractable arm 206 is arch-shaped. In some embodiments, the side panels 208a and b serve two purposes, which include (1) supporting the retractable arm 206 and (2) supporting the screen 210. The screen 210 is attached to the side panels 208a and b. Although in the embodiment of FIG. 2, the side panels 208a and b are partial arches, in other embodiments, the partial arches and the side panels 208a and b can be replaced by a full arch or other shapes. In some embodiments, the side panels 208a and b, the retractable arm 206 and the screen 210 are shaped to conform to the shape of the MRI bore of the magnet housing 108.

The pivots 212a and b are attached to the side panels 208a and b and the retractable arm 206. The retractable arm 206 pivots (or rotates) with respect to the side panels 208a and b. The retractable arm 206 rotates on the pivots 212a and b from a position illustrated in FIG. 2 (in which the mirror 204 is deployed) to a position in which the retractable arm 206 is vertical and parallel to the screen 210. In alternative embodiments, the retractable arm 206 is a telescoping arm. In other embodiments, the retractable arm 206 is a multi-joint folding arm. However, the embodiment depicted in the FIG. 2 for the retractable arm 206 is simpler and therefore more reliable than a telescoping arm or multi-joint folding arm.

In some embodiments, in the deployed position, a plane in which the surface of the mirror 204 lies makes a 40-degree angle (angle 220) with the viewing plane 218, which is a plane that is perpendicular to a plane in which the screen 210 lies and which is parallel to the floor or a surface of the bed 110 that the patient lies upon (the angle 222 is 90 degrees). The appropriate angle at which to place the mirror 204 depends on the angle of the patient's head while receiving the MRI. In other embodiments, the angle 220 is different than 40 degrees (e.g., 35 to 60 degrees). The viewing plane 218 is the plane that the viewer imagines they are looking at while viewing images, via the mirror 204. The viewing plane 218 is drawn using dashed lines to indicate that the viewing plane 218 is not a physical structure but is a construct used to illustrate the angle of orientation of the mirror 204. In some embodiments, to place the mirror at 40 degrees with respect to the viewing plane, the retractable arm 206 extends to an angle of 40 degrees with respect to the screen 210 (in some embodiments, the angle between the mirror 204 and the viewing plane 218 is the same as the angle between the retractable arm 206 and the screen 210).

The feet 214a-d are attached to the bottom of the side panels 208a and b. The feet 214a-d interlock and engage with the bed 216, which is secured onto, or is part of, the bed 110.

The image (from the projector 112) is projected onto the back side of the screen 210, which is the side of the screen 210 that is not visible in FIG. 2 and is the side that faces away from the rest of the screen assembly 132. Projecting an image on the backside of the screen 210 causes an image to form on the front side of the screen 210, which is the side of the screen 210 that is visible in FIG. 2 and the side that faces the mirror 204. The image formed on the front sides of the screen 210 then travels to the mirror 204, which reflects the image to the patient in the head coil 202. In some embodiments, the components of the screen assembly 132 are made from a nonconductive material. In some embodiments, the nonconductive material is a plastic. In some embodiments, the nonconductive material is a thermoplastic. In some embodiments, the nonconductive material is acrylate, poly(methyl methacrylate.

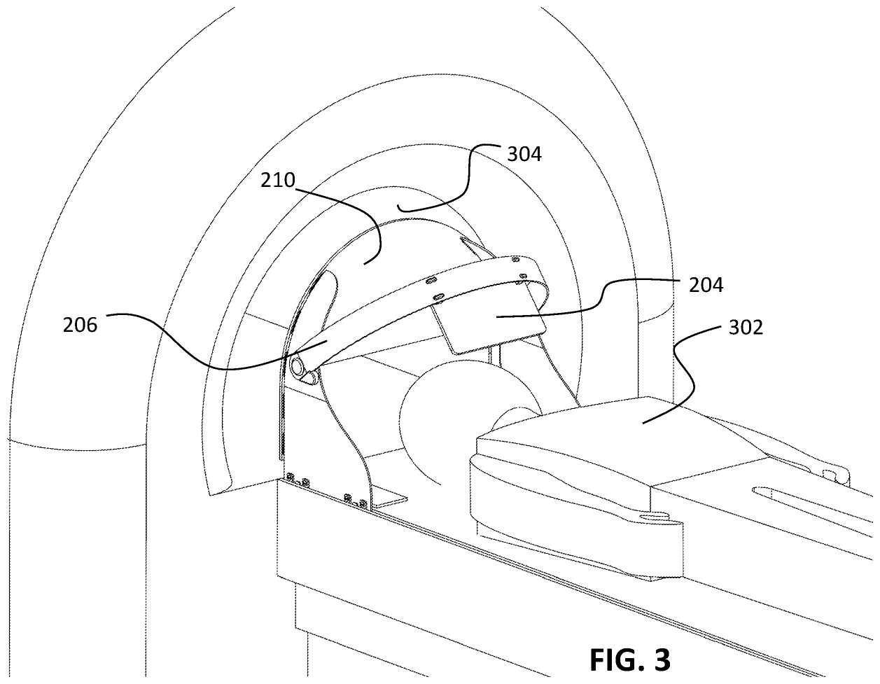

FIG. 3 illustrates a patient 302 using the viewing system of FIG. 1. The patient 302 lies at least partially in the MRI bore 304 (which is within the magnet housing 108) with the screen 210 behind the patient's head (which in the embodiment of FIG. 3 is the end of the head furthest from the patient's feet). The retractable arm 206 holds the mirror 204 over the patient 302, which in some embodiments is in the MRI bore 304. In the embodiment of FIG. 3, the screen 210 is further from the center of the magnet housing 108 than the retractable arm 206. Extending the retractable arm 206 to deploy the mirror 204, causes the retractable arm 206 to move in a direction further toward the interior of the magnet housing 108.

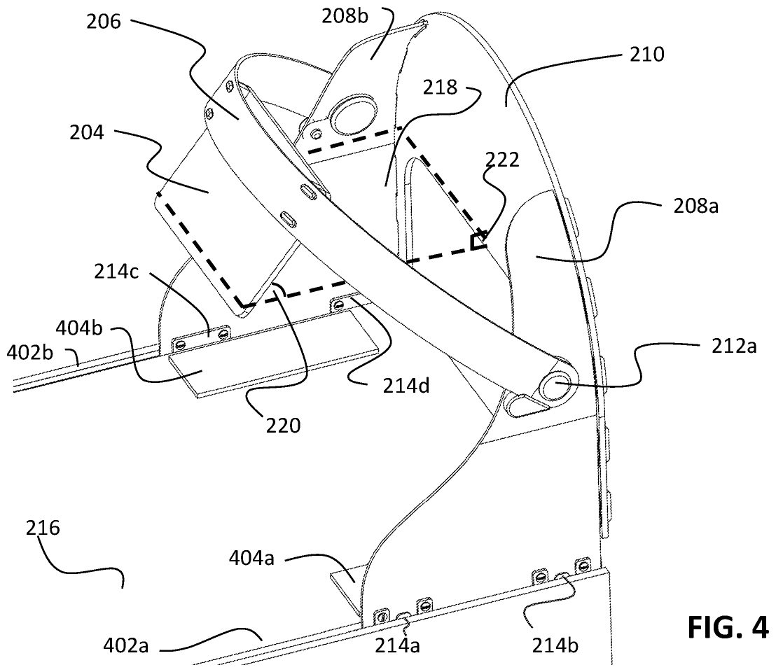

FIG. 4 illustrates the screen assembly 132 without the magnet housing 108 and the head coil 202, providing a better view of the screen assembly 132. In some embodiments, tracks 402a and b are in the bed surface 216, and plates 404a and b are part of the bed 110. Other MRI systems have different features.

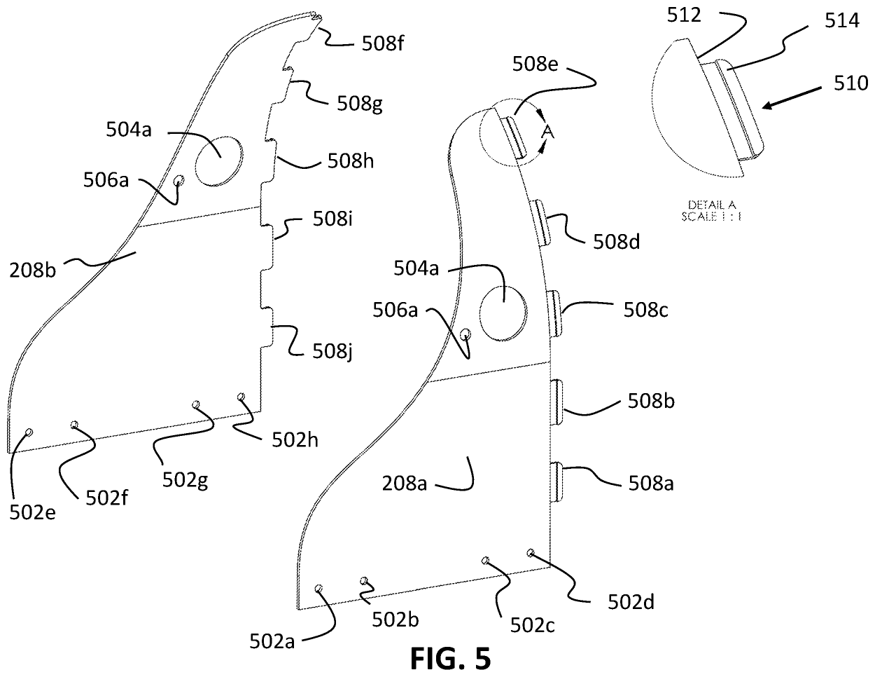

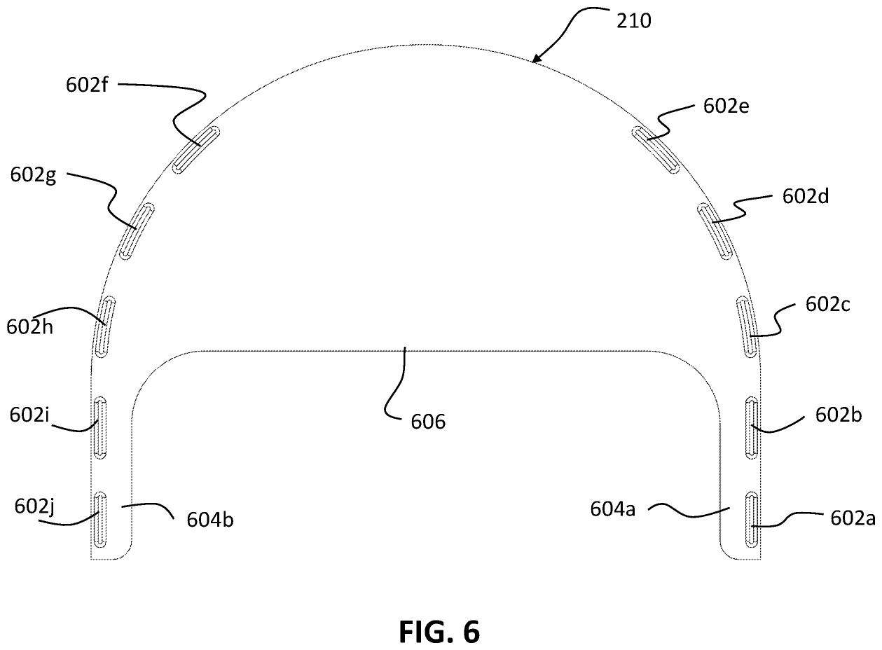

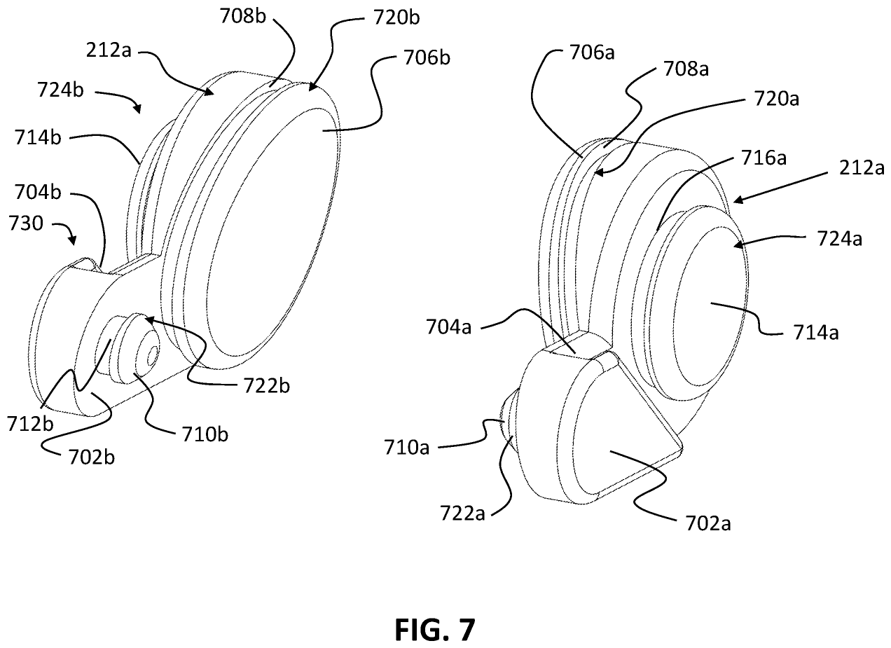

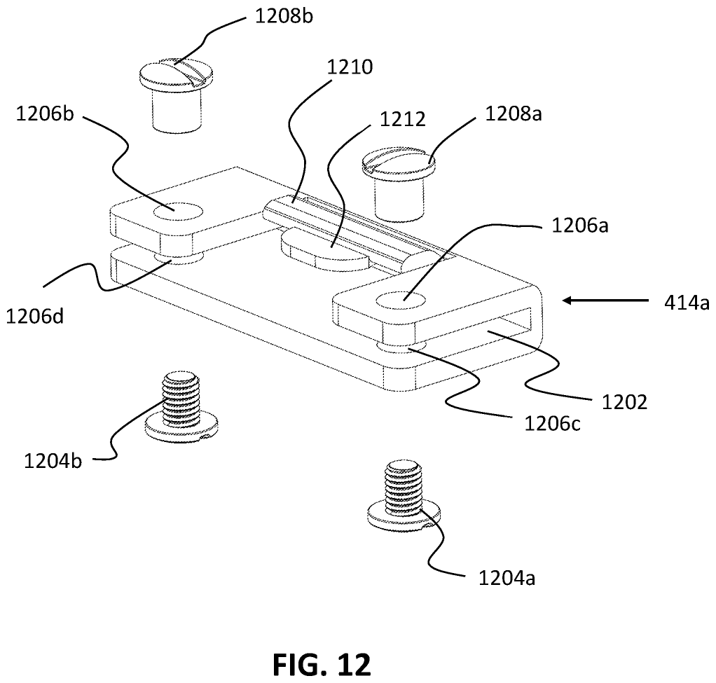

FIG. 5 illustrates some embodiments of the side panels 208a and b, which include holes 502a-h, holes 504a and b and 506a and b and tabs 508a-j. FIG. 5 also illustrates a Detail 510. The Detail 510 illustrates a cross-sectional view of the tab 508e, which has a body 512 and a head 514. The holes 502a-h are discussed below in conjunction with FIG. 12. The holes 504a and b and 506a and b are discussed in conjunction with FIG. 7. The tabs 508a-j are discussed further in conjunction with FIG. 6 (the screen 210 is illustrated, and discussed further, in conjunction with FIG. 6).

FIG. 6 illustrates various embodiments of the screen 210. The screen 210 includes slots 602a-j, legs 604a and b and a body 606. The slots 602a-j receive the tabs 508a-j (shown in FIG. 5) to hold the screen 210 to the side panels 208a and b. In some embodiments, the tabs 508a-j have heads (e.g., the head 514) that are thicker than the bodies of the tabs 508a-j. In some embodiments, the screen 210 snaps onto the one end of the side panels 208a and b. In some embodiments, the tabs 508a-j each have a structure (as shown in the Detail 510) shaped like a half arrow, so that it is easier to insert the tabs 508a-j into the slots 602a-j than to remove the tabs 508a-j from the slots 602a-j. In alternative embodiments, the screen 210 is attached between the side panels 208a and b, and the screen 210 has tabs that engage with slots on the side panels 208a and b. In embodiments in which the side panels 208a and b are replaced by a single arch, slots are also included closer to the top of the screen 210. In some embodiments, the legs 604a and b lie at the sides of the bed 110. The body 606 (which lies above the bed 110) is the part of the screen 210 that functions as a screen.

FIG. 7 illustrates some embodiments of the pivots 212a and b (see FIGS. 2 and 4, which illustrate where the pivot 212a is found). The pivots 212a and b include arms 702a and b having slots 704a and b, heads 706a and b, necks 708a and b, heads 710a and b, necks 712a and b, heads 714a and b and necks 716a and b (the neck 716b is not visible from the angle of view of FIG. 7, but is identical to the neck 716a). The pivots 212a and b are mirror images of one another. The head-neck combinations 706a/708a, 706b/708b, head-neck combinations 710a/712a and 710b/712b and the head-neck combinations 714a/716a and 714b/716b form button structures 720a and b, 722a and b and 724 a and b, respectively. In some embodiments, each of the button structures 720a and b, 722a and b and 724 a and b are one integral structure. In other embodiments, the heads 706a and b, the heads 710a and b and the heads 714a and b screw onto (or otherwise attach to) the necks 708a and b, the necks 712a and b and the necks 716a and b. The holes 504a and b and 506a and b (FIG. 5) receive the button structures 720a and b and 722a and b, respectively. In some embodiments, the button structures 720a and b and 722a and b snap into the holes 504a and b and 506a and b (FIG. 5).

When assembled, the necks 708a and b and 712a and b rest in the holes 504a and b, 506a and b (FIG. 5) of the side panels 208a and b, keeping the pivots 212a and b rigidly mounted in fixed positions on the side panels 208a and b. The heads 706a and b and the heads 710a and b keep the side panels 208a and b from sliding off the necks 708a and b and 712a and b, respectively. Engaging the two pairs of holes 504a and b and 506a and b with the two pairs of the necks 708a and b and 712a and b (which are on the pivots 212a and b) keeps the pivots 212a and b from rotating with respect to the side panels 208a and b, respectively. In an alternative embodiment, one or more of the holes 504a and b and 506a on the side panels are replaced with button structures, and one or more of the button structures 720a and b, 722a and b are replaced by openings or holes that accept the button structures on the side panels. The slots 704a and b receive the retractable arm 206, and when the mirror 204 is deployed the retractable arm 206 rests on the slots 704a and b, holding the retractable arm 206 in place, preventing the retractable arm 206 from falling.

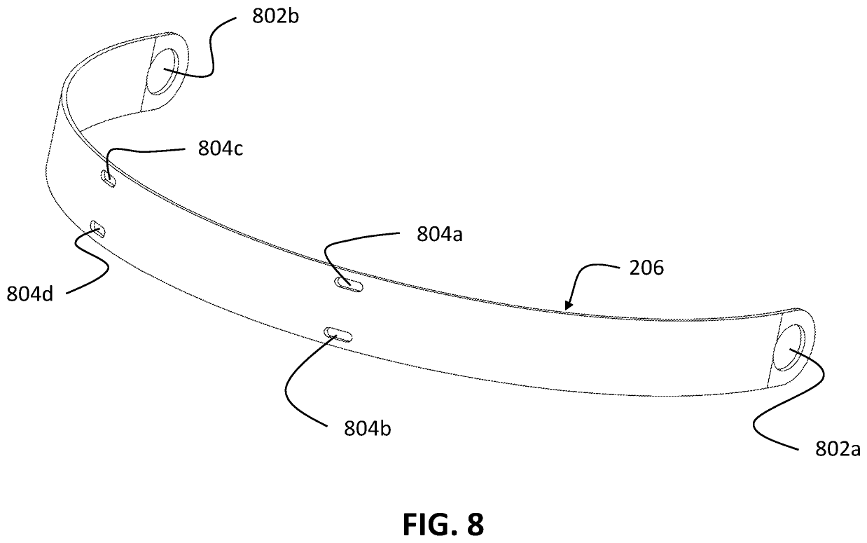

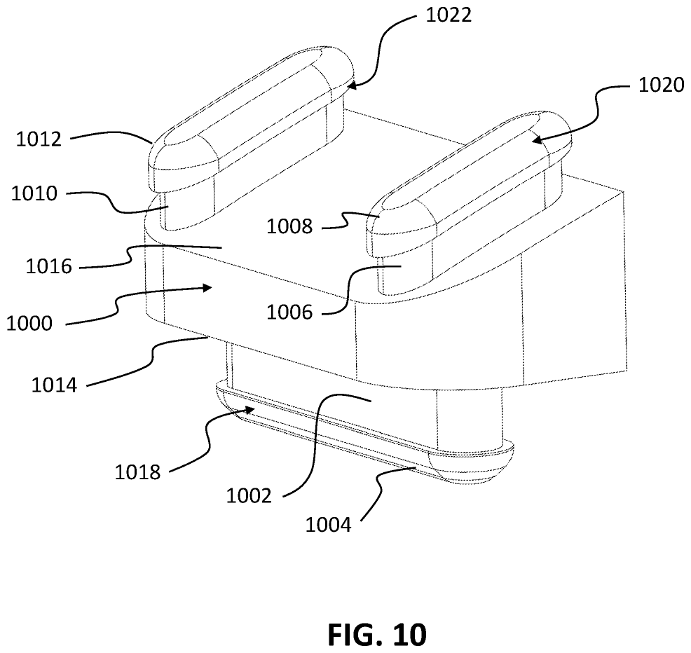

FIG. 8 illustrates the retractable arm 206 that supports the mirror 204. The retractable arm 206 includes holes 802a and b and slots 804a-d. The slots 804a-d are discussed in conjunction with FIG. 10, below. The holes 802a and b engage the necks 716a and b of the button structures 724a and b, and the necks 716a and b rest in holes 802a and b (FIG. 8) at the ends of the retractable arm 206, respectively, allowing the retractable arm 206 to rotate on the necks 716a and b. The heads 714a and b keep the retractable arm 206 from sliding off the pivots 212a and b. In other embodiments, the retractable arm 206 has one or both button structures and the pivots 212a and b include openings that engage the button structures (or an alternative rotatable structure attaches the retractable arm 206 to the pivots 212a and b).

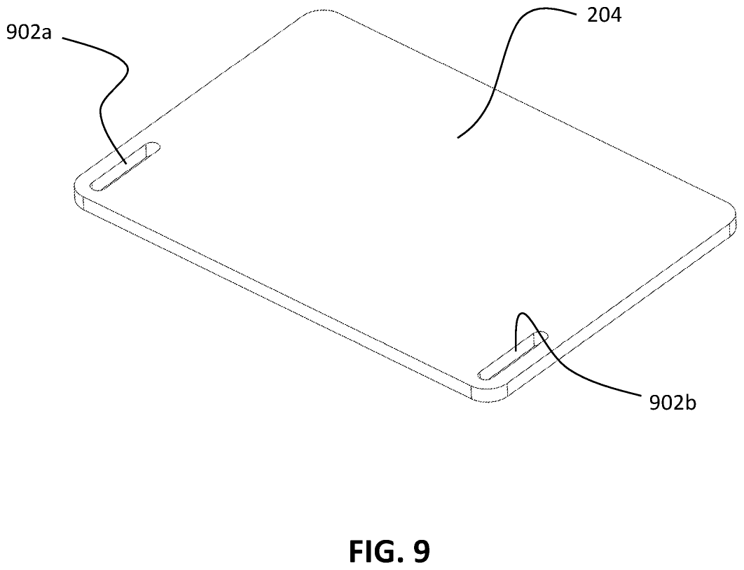

FIG. 9 illustrates the mirror 204, which includes two slots 902a and b, which will also be discussed in conjunction with FIG. 10.

FIG. 10 illustrates a connector 1000, which includes a neck 1002, a head 1004, a neck 1006, a head 1008, a neck 1010, a head 1012 and surfaces 1014 and 1016. The neck-head combinations neck 1002/head 1004, the neck 1006/head 1008 and the neck 1010/head 1012 form button structures 1018, 1020 and 1022, respectively. In some embodiments, the button structures 1018, 1020 and 1022 are each one integral piece of material. In some embodiments, two connectors that are identical to connector 1000 are included, and there is one connector for each of the slots 902a and b. The neck 1002 engages one of the slots 902a and the head 1004 keeps the mirror 204 from slipping off the neck 1002. Similarly, the necks 1006 and 1010 engage either the slots 804a and b or 804c and d. In some embodiments, the necks 1002, 1006 and 1010 are noncircular, which helps keep the connector 1000 in a fixed position with respect to the retractable arm 206 and mirror 204. In some embodiments, the button structures 1018, 1020 and 1022 snap into the slots 804a and b and 902a or into the slots one of the slots 804c and d and 902b. In some embodiments, the heads 1004, 1008 and 1012 have an arrow-shaped profile. In some embodiments, the surfaces of the heads 1004, which are furthest from the surfaces 1014 and 1016 are sloped to facilitate inserting the heads 1004, 1008 and 1012 into the slots 902a (or the slot 902b) and 804a and b (or 804c and d). In some embodiments, the heads 1004, 1008 and 1012 have an arrow-shaped profile. The heads 1008 and 1012 keep the slots 804a and b or 804c and d from sliding off the necks 1006 and 1010.

Although the slots 804a-d and 902a and b are on the mirror 204 and the retractable arm 206 and the button structures 1018, 1020 and 1022 are on the connector 1000, in other embodiments, one or more of the button structures are on the mirror 204 and the retractable arm 206 and the connector has one or more openings that engage the button structures on the mirror 204 and the retractable arm 206.

Although in the embodiment of FIG. 10 the button structures 1018, 1020 and 1022 are rectangular, in other embodiments a different shape is used or different fasteners are used.

The surfaces 1014 and 1016 are not parallel to one another but are angled so that the surface 1014 rests against and is parallel to the surface of the mirror 204, and the surface 1016 is angled to match the curvature of the retractable arm 206. When both of the connectors are attached to the retractable arm 206, each of the slots 804a-d is engaged.

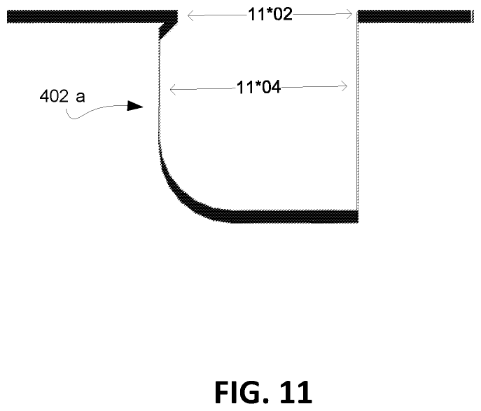

FIG. 11 illustrates a cross-section 1100 of the track 402a, which is a mirror image of the cross-section of the track 402b. The track 402a includes an opening 1102, which is narrower than an interior 1104. The opening 1102 and the interior 1104 are discussed further in conjunction with FIG. 12.

FIG. 12 illustrates the foot 214a. The other feet 214b-d are the same as the foot 214a. The foot 214a includes a slot 1202, screws 1204a and b, holes 1206a-d, caps 1208a and b, a tab 1210 and a tab 1212. The slot 1202 receives the bottom of one of the side panels 208a or b, and the screws 1204a and b engage two of the holes 502a-h in the bottom of the side panels 208a or b and in the holes 1206a-d to hold the foot 214a to the bottom of the side panels 208a or b. The caps 1208a and b engage the screws 1204a and b holding the screws 1204a and b in place. In other embodiments, the screws 1204a and d are not present. In some embodiments, the feet 214a-d are integral parts of the side panels 208a and b. In some embodiments, the feet clamp/clip onto the MRI system 100. In some embodiments, the tab 1210 depresses allowing the foot 214a to be inserted into the track 402a. The tab 1210 is also sloped on the side that faces the track 402a before insertion. The slope causes the tab 1210 to depress as the foot 214a is pushed into the track 432a, further facilitating the insertion of the foot 214a into the track 402a. As a result of the tab 1210, the width of the foot 214a is wider than the opening 1102 of the track 402a when the tab 1210 is not depressed. Consequently, as a result of the narrowness of the opening 1102, the opening 1102 holds the foot 214a within the interior 1104 of the track 402a. In this manner, as seen in FIG. 4, the feet 214a-d engage in the tracks (or troughs) 402a and b, via their tabs, and are attached to the side panels 208a and b, via the holes 502a-h (thereby holding the side panels 208a and b and the screen viewing system 132 to the bed 110). Nonetheless, after insertion, the tab 1210 can be depressed by hand to release the tab 1210 from the track 402a. In some embodiments, the tab 1212 is an extension of tab 1210. In some embodiments, tabs 1210 and 1212 form one integral piece of material. The tab 1212 is depressed manually, thereby depressing tab 1210, allowing the foot 214a to be removed from the interior 1104 after being inserted.

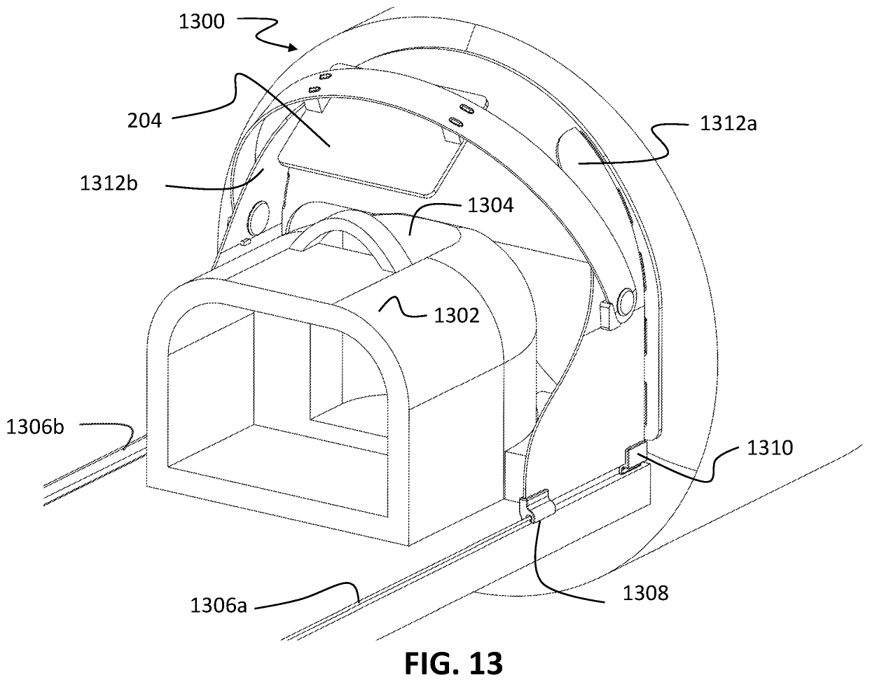

FIG. 13 illustrates some embodiments of an MRI system 1300, which includes a head coil 1302 having an opening 1304. The MRI system 1300 also includes a rail 1306a, feet 1308 and 1310 and side panels 1312a and b. Similar to the system of FIG. 2, the mirror 204 is positioned over the opening 1304 (of the head coil 1302) at an angle so that the patient can view the image on the screen. The rail 1306a guides the surface that the patient lies on while traveling in and out of the MRI system 1300. The foot 1308 grasps the bottom of the side panel 1312a and the rail 1306a. The foot 1310 guides the side panel 1312a within the rail 1306a. The side panels 1312a and b are similar to the side panels 208a and b. However, the side panels 1312a and b do not need to have the holes 502a-h, because the feet 1308 and 1310 do not have screws (in contrast to the feet 214a-d). The side panels 1312a and b and the side panels 208a and can be swapped for one another so long as the appropriate feet are used, and the feet are chosen based on the MRI system to which the side panels need to be attached to.

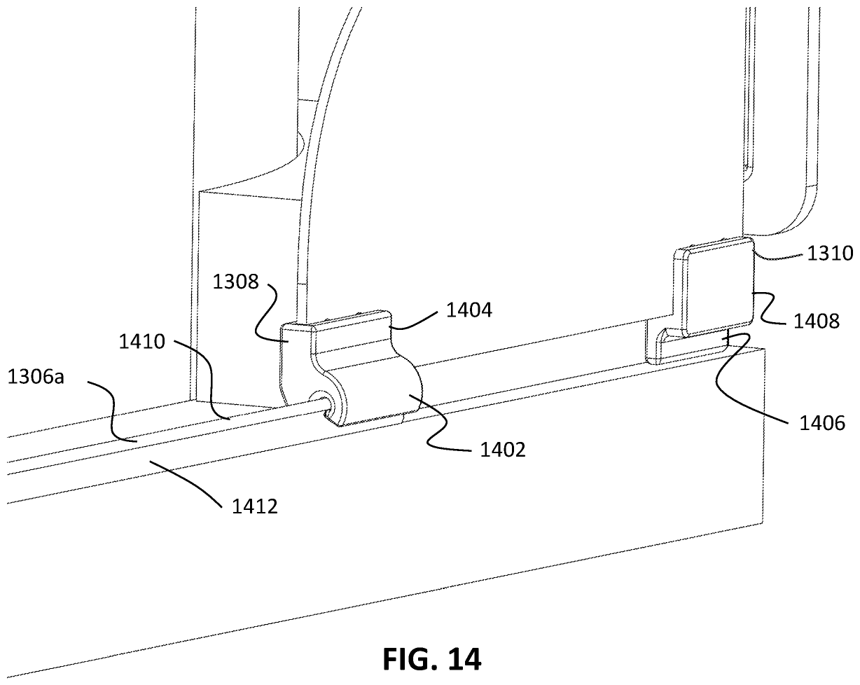

FIG. 14 illustrates some embodiments of the MRI systems 1300, which illustrates (1) a hand 1402 and a clamp 1404 of the foot 1308, (2) a base 1406 and a clamp 1408 of the foot 1308 and (3) a head 1412 and a body 1414 of the rail 1306a. The clamps 1404 and 1408 are the parts of feet 1308 and 1310 that attach to the side panels 1312a and b. The hand 1402 has two fingers, which grasp the rail 1306a. Similar to the foot 214a, the head 1402 of the rail 1306a is wider than the body 1404 of the rail 1306. Similar to the tracks 402a and b, the hand 1402 has fingers that form a track whose interior is wider than the opening, so as to grasp the head 1410 of the end of the rail 1306a (the head of the rail 1410 is above the body 1412 of the rail 1306a). In some embodiments, the clamp 1408 is wider than the base 1406.

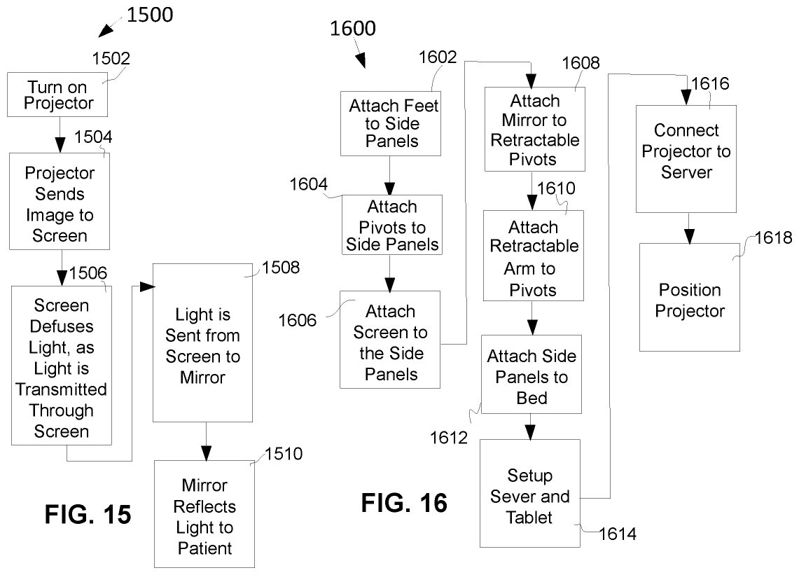

FIG. 15 illustrates some embodiments of a method 1500 of the screen system 132. In a step 1502, the projector 112 is turned on. In a step 1504, the projector 112 sends an image to a back side of the screen 210 (see the discussion of FIG. 2). In a step 1506, the image is diffused and transmitted through the screen 210 forming an image on the front of the screen 210 (see the discussion of FIG. 2). In a step 1508, the image is transmitted to the mirror 204. In a step 1510, the image is reflected by the mirror 204 to the patient (see the discussion of FIG. 2).

FIG. 16 illustrates some embodiments of a method 1600 of setting up the projector system of FIG. 1 (see the discussion of FIG. 1). In a step 1602, the feet 214a-d are attached to the side panels 208a and b (see the discussion of FIGS. 2, 4, 11 and 12). In a step 1604, the pivots 212a and b are attached to the side panels 208a and b (see the discussion of FIGS. 2, 4, 5 and 7). In a step 1606, the screen 210 is attached to the side panels 208a and b (see the discussion of FIGS. 2 and 4-6). In a step 1608, the mirror 204 is attached to the retractable arm 206 (see the discussion of FIGS. 2-4 and 8-10). In a step 1610, the retractable arm 206 is attached to the pivots 212a and b (see the discussion of FIGS. 2-4, 7 and 8). In a step 1612, the side panels 208a and b are attached to the bed (see the discussion of FIGS. 2, 4, 11 and 12).

In a step 1614, the server 120 and the client device 122 are set up (see the discussion of FIG. 1). In a step 1616, the projector 112 is attached to the server 120 (see the discussion of FIG. 1). In a step 1618, the projector 112 is positioned to focus the image on the screen 210 (see the discussion of FIGS. 1-4).

### Examples of Embodiments

Embodiment 1. An MRI projector viewing system (e.g., screen assembly 132) comprising:
two side panels (208a and b),
two pivots (212a and b);
a screen (210) attached to the two side panels (208a and b), the screen being translucent; the two side panels support the two pivots (212a and b);
a retractable arm (206) being rotatably mounted to the two side panels (208a and b); and a mirror (204) attached to the retractable arm; and
the retractable arm (206) having
a first position, which is an extended position, in which the mirror (204) is deployed and the retractable arm (206) is extended for viewing an image reflected from the screen (210) and a second position in which the mirror (204) is retracted.

Embodiment 2. The MRI projector viewing system (e.g., screen assembly 132) of Embodiments 1-20,
each of the two pivots (212a and b) having an arm (702a or b), the arm of each pivot of the two pivots having a slot (704a or b), when the retractable arm (206) is in the extended position, the retractable arm (206) rests in each slot (704a or b) of each arm of the two pivots (212a or b).

Embodiment 3. The MRI projector viewing system (e.g., screen assembly 132) of Embodiments 1-20, the retractable arm (206) having an arc shape.

Embodiment 4. The MRI projector viewing system (e.g., screen assembly 132) of Embodiments 1-20, further comprising at least one connector (1000) connecting the retractable arm (206) to the mirror (204).

Embodiment 5. The MRI projector viewing system (e.g., screen assembly 132) of Embodiments 1-20 or 4, one of the connector (1000) and the mirror (204) having a button structure, another of the connector (1000) and the mirror (204) having an opening that engages the button structure fastening the mirror (204) to the connector (1000).

Embodiment 6. The MRI projector viewing system (e.g., screen assembly 132) of Embodiments 1-20 or 5, the button structure and the opening that fasten the mirror to the connector being a first button structure and a first opening, respectively, one of the connector and the retractable arm having a second button structure, another of the connector and the retractable arm having a second opening that engages the second button structure fastening the connector to the retractable arm (206).

Embodiment 7. The MRI projector viewing system of Embodiments 1-20 or 4, one of the connector (1000) and the retractable arm (206) having a button structure, and another of the connector (1000) and the retractable arm (206) having an opening that engages the button structure fastening the connector (1000) to the retractable arm (206).

Embodiment 8. The MRI projector viewing system (e.g., screen assembly 132) of Embodiments 1-20, one of the retractable arm (206) and the two pivots (212a or b) having two holes (504a or b) and another of the retractable arm (206) and the two pivots (212a or b) having two button structures (724a or b) that engage the two holes (802a or b), allowing the retractable arm (206) to pivot on the two pivots (212a or b).

Embodiment 9. The MRI projector viewing system of Embodiments 1-20, at least one pivot of the two pivots having two button structures and the two side panels each having two holes that engage the two button structures, that hold the at least one pivot of the two pivots to the two side panels, without rotating.

Embodiment 10. The MRI projector viewing system (e.g., screen assembly 132) of Embodiments 1-20, further comprising feet (214a-d) that attach to a bottom of the side panels (208a or b) and interlock with a track (402a or b) in a bed (216) attached to a bed (110) of an MRI system (100).

Embodiment 11. The MRI projector viewing system (e.g., screen assembly 132) of Embodiments 1-20, further comprising a projector (112) positioned over a bed (110) of an MRI system (100).

Embodiment 12. The MRI projector viewing system (e.g., screen assembly 132) of Embodiments 1-20, one of the screen (210) and the two side panels (208a or b) having slots (602a-j) and another of the screen (210) and the two side panels (208a or b) having tabs (508a-j) that interlock with the slots (602a-j), connecting the two side panels (208a and b) to the screen (210).

Embodiment 13. An MRI projecting viewing system (e.g., screen assembly 132) comprising:
a projector (112) located over a bed (110) of an MRI system (100);
a screen (210) being mounted at a MRI bore of the MRI system (100) and being translucent, the projector (112) located on a first side of a screen (210); and
a mirror (204) mounted on a second side of the screen (210); and
the mirror (204) being angled to reflect images from the second sides of the screen (210) toward a bed of the MRI system (100).

Embodiment 14. A method (1500) comprising:
sending an image from a projector (112) located opposite an MRI bore in a straight line to a first side of a screen (210);
the image, after being incident on the first side of the screen (210), being transmitted through the screen (210) causing the image to be formed on a second side of the screen (210); and
reflecting the image, by a mirror (204) from the second side of the screen (210) toward a location where a patient lies when undergoing an MRI.

Embodiment 15. The method of Embodiments 1-20, the mirror (204) being supported by a retractable arm (206).

Embodiment 16. The method of Embodiments 1-20, the mirror (204) being supported by a retractable arm (206);
the screen (210) being connected to side panels (208a and b), the side panels (208a and b) supporting a pivot (212a or b) upon which the retracted arm (206) rotates.

Embodiment 17. The method of Embodiments 1-20, the mirror (204) being supported by a retractable arm (206);
the screen (210) being connected to side panels (208a and b), the side panels (208a and b) supporting a pivot (212a or b) upon which the retracted arm (206) rotates;
the method further comprising
extending the retractable arm (206) from a retracted position to an extended position, by rotating the retractable arm (206) on the pivot connected to one side panels of the side panels;
the pivot (212a or b) having an arm (702a or b), the arm of the pivot having a slot, when the retractable arm is extended, the retractable arm rests in the slot (704a or b) of the pivot (212a or b).

Embodiment 18. The method of Embodiments 1-20,
the mirror (204) being supported by a retractable arm (206);
the retractable arm (206) having an arc shape.

Embodiment 19. The method of Embodiments 1-20,
the mirror (204) being supported by a retractable arm (206);
wherein a connector (1000) connects the retractable arm (206) to the mirror (204).

Embodiment 20. The method of Embodiments 1-20, the mirror (204) being supported by a retractable arm (206);
wherein a connector (1000) connects the retractable arm (206) to the mirror (204); wherein one of the connector (1000) and the mirror (204) having a button structure, another of the connector (1000) and the mirror (204) having an opening that engages the button structure fastening the mirror (204) to the connector (1000).

### Alternatives and Extension

The head-neck combinations of heads and necks form button structures. In other embodiments, other button structures can be used. The holes and slots and button structures, nuts, bolts, screws and screwcaps described above (e.g., the holes 502a-h, 504a and b, 802a and b, and 1206a and b; the slots 602a-k, 704a and b, 804a-d, 902a and b, 902a and 1202; the necks 708a and b, 712a and b, 716a and b, 1002, 1006 and 1010; the heads 706a and b, 710a and b, 714a and b, 1004, 1008 and 1012; the foot 214a, the screws 1204a and b, the caps 1208a and b and the tabs 1110 and 1210) form fasteners and parts of fasteners. In other embodiments, other fasteners are used.

Although the disclosed method and apparatus are described the projector is attached to the server. Above in terms of various examples of embodiments and implementations, it should be understood that the particular features, aspects and functionality described in one or more of the individual embodiments are not limited in their applicability to the particular embodiment with which they are described. Thus, the breadth and scope of the claimed invention should not be limited by any of the examples provided in describing the above disclosed embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide examples of instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosed method and apparatus may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described with the aid of block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. An MRI (Magnetic Resonance Imaging) projector viewing system comprising:
two side panels,
a screen attached to the two side panels, the screen being translucent;
two pivots;
the two side panels support the two pivots;
a retractable arm being rotatably mounted to the two side panels; and
a mirror attached to the retractable arm; and
the retractable arm having
a first position, which is an extended position, in which the mirror is deployed and the retractable arm is extended for viewing an image reflected from the screen and
a second position in which the mirror is retracted.

2. The MRI projector viewing system of claim 1,
each of the two pivots having an arm, the arm of each pivot of the two pivots having a slot, when the retractable arm is in the extended position, the retractable arm rests in each slot of each arm of the two pivots.

3. The MRI projector viewing system of claim 1, the retractable arm having an arc shape.

4. The MRI projector viewing system of claim 1, further comprising at least one connector connecting the retractable arm to the mirror.

5. The MRI projector viewing system of claim 4, one of the connector and the mirror having a button structure, another of the connector and the mirror having an opening that engages the button structure fastening the mirror to the connector.

6. The MRI projector viewing system of claim 5, the button structure and the opening that fastens the mirror to the connector being a first button structure and a first opening, respectively one of the connector and the retractable arm having a second button structure, another of the connector and the retractable arm having a second opening that engages the second button structure fastening the connector to the retractable arm.

7. The MRI projector viewing system of claim 4, one of the connector and the retractable arm having a button structure, another of the connector and the retractable arm having an opening that engages the button structure fastening the connector to the retractable arm.

8. The MRI projector viewing system of claim 1, one of the retractable arm and the two pivots having two holes and another of the retractable arm and the two pivots having two button structures that engage the two holes, allowing the retractable arm to rotate on the two pivots.

9. The MRI projector viewing system of claim 1,
at least one pivot of the two pivots having two button structures and the two side panels each having two holes that engage the two button structures, that hold the at least one pivot of the two pivots to the two side panels, without rotating.

10. The MRI projector viewing system of claim 1, further comprising feet that attach to a bottom of the side panels and interlock with a bed of an MRI system.

11. The MRI projector viewing system of claim 1, further comprising a projector positioned over a bed of an MRI system.

12. The MRI projector viewing system of claim 1, one of the screen and the side panels having slots and another of the screen and the side panels having tabs that interlock with the slots, connecting the side panels to the screen.

13. An MRI (Magnetic Resonance Imaging) projecting viewing system comprising:
a projector located over a bed of an MRI system;
a translucent screen being mounted at a MRI bore of the MRI system, the projector located on a first side of a screen; and
a mirror mounted on a second side of the translucent screen; and
the mirror being angled to reflect images from the second side of the screen toward a bed of the MRI system.

14. A method comprising:
sending an image from a projector located opposite a MRI bore in a straight line to a first side of a screen;
the image, after being incident on the first side of the screen, being transmitted through the screen causing the image to be formed on a second side of the screen; and
reflecting the image, by a mirror from the second side of the screen toward a location where a patient lies when undergoing an MRI (Magnetic Resonance Imaging).

15. The method of claim 14, the mirror being supported by a retractable arm.

16. The method of claim 15, the screen being connected to side panels, the side panels supporting a pivot upon which the retracted arm rotates.

17. The method of claim 16,
extending the retractable arm from a retracted position to an extended position, by rotating the retractable arm on the pivot connected to one side panels of the side panels;
the pivot having an arm, the arm of the pivot having a slot, and when the retractable arm is extended, the retractable arm rests in the slot of the pivot.

18. The method of claim 15, the retractable arm having an arc shape.

19. The method of claim 15, wherein a connector connects the retractable arm to the mirror.

20. The method of claim 19, wherein one of the connector and the mirror having a button structure, another of the connector and the mirror having an opening that engages the button structure fastening the mirror to the connector.
